(19) United States
(12) Patent Application Publication
(10) Pub. No.: US 2018/0175646 A1
(43) Pub. Date: Jun. 21, 2018

(54) CHARGING CABINET

(71) Applicant: CHEN-SOURCE INC., Taoyuan City (TW)

(72) Inventor: Yun-Hao CHEN, Taoyuan City (TW)

(21) Appl. No.: 15/379,840

(22) Filed: Dec. 15, 2016

(51) Int. Cl. H02J 7/00; H01R 31/06; H05K 5/03; H05K 5/02

(52) U.S. Cl. CPC H02J 7/0044; H01R 31/06; H02J 7/0052; H02J 2007/0059; H05K 5/0221; H05K 5/0226; H05K 5/0213; H05K 5/03

(57) ABSTRACT

The present disclosure illustrates a charging cabinet in which a main body comprises a frame defining a receiving space, a panel disposed on a front surface of the frame, a hinge lid movably disposed on the panel corresponding in position to the receiving space, a locking device disposed at a side of the hinge lid and configured to control open or lock of the hinge lid. The power supply device comprises a power input module connected with an external power source for supplying power to a power socket module and an expansion connection module which comprise a socket and an adaptor socket respectively. An electronic device can be placed into the receiving space to be charged through the power socket module or expansion connection module, and the hinge lid can be locked by the locking device, so as to achieve anti-theft effect.

### BACKGROUND OF THE INVENTION

### 1. Field of the Invention

The present disclosure relates to a charging cabinet, more particularly to a charging cabinet in which a main body includes a frame defining a receiving space inside, a panel located at the front of the frame, and a hinge lid pivotally connected to the panel corresponding in position to the receiving space. An electronic device can be placed into the receiving space to be charged through a power socket module or an expansion connection module of the power supply device, and the hinge lid can be locked by a locking device located at a side thereof, so as to achieve anti-theft effect.

### 2. Description of the Related Art

In recent years, electronic technology and multimedia information technology are rapidly developed, so electronic products (such as smartphone, tablet computer, notebook computer, and personal digital assistant and so on) become more powerful, but their sizes are developed to be more compact, lighter and smaller. The mainstream electronic products have features of small size, light weight, and easy carrying, and are equipped with software and hardware which are continuously developed to provide more flexibility and practicability in use, so they can be more widely applied and have become indispensable devices in people's life, work and entertainment.

The powerful electronic product (such as smartphone, tablet computer, and notebook computer and so on) also consumes more power, so it is easy to exhaust battery power of the electronic product when the user keeps operating the electronic product during movement, and user has to find a socket to charge the battery of the electronic product for further operation.

However, away from home, for example, when the user goes to department store, and hospital and so on, it is not easy for the user to find the socket for charging. Even though the user can find the socket to charge the electric device, the user has to stay around the socket to wait for completion of a charging process and prevent the electronic product from being stolen during the charging process. As a result, during the charging process, the user wastes a lot of time in waiting and cannot do what he or her wants to do, that is why most people would rather not charge the electronic products until they go back home or offices, and it causes inconvenience in using the electronic products.

What is need is to develop a charging cabinet to solve aforesaid problems.

### SUMMARY OF THE INVENTION

Therefore, in order to solve aforesaid problems, the inventors of the present disclosure put years of practical experience into data collection, research, design and test, and finally succeeded in developing a charging cabinet.

A primary objective of the present disclosure is that a frame of a main body of the charging cabinet has a receiving space to place at least one electronic device, so that it is easier for the user to properly arrange the entire space configuration for the electronic device and to centralize management of the electronic device, and at least one electronic device can be electrically inserted in the at least one socket or adaptor socket disposed on a support plate of the frame, so that a power input module of the power supply device can be connected with an external power source to charge at least one electronic device, whereby the user does not need to search other host or power source for charging. As a result, the working hour and cost for charging electronic devices individually can be reduced, and the efficiency of charging operation and convenience in use can be improved.

A secondary objective of the present disclosure is that the user can open the hinge lid to place the electronic device into the receiving space of the frame for storage or charging operation, or take the electronic device out of the receiving space; alternatively, the user can close the hinge lid to lock the hinge lid by the locking device, whereby the hinge lid can be in a locked state to prevent the electronic device in the receiving space from being lost or stolen. Therefore, the charging cabinet of the present disclosure has anti-theft function.

### BRIEF DESCRIPTION OF THE DRAWINGS

The detailed structure, operating principle and effects of the present invention will now be described in more details hereinafter with reference to the accompanying drawings that show various embodiments of the invention as follows.

FIG. 1 is an elevational view of a charging cabinet of the present disclosure.

FIG. 2 is an exploded view of the charging cabinet of the present disclosure.

FIG. 3 is an exploded view of the charging cabinet of the present disclosure, when viewed from another angle.

FIG. 4 is a partial enlarged view of a locking device before being unlocked, in accordance with the present disclosure.

FIG. 5 is a partial enlarged view of the locking device after being unlocked, in accordance with the present disclosure.

FIG. 6 is an elevational view of the charging cabinet of the present disclosure, before an electronic device is placed in the charging cabinet.

FIG. 7 is an elevational view showing the electronic device is charged in the charging cabinet of the present disclosure.

### DETAILED DESCRIPTION OF THE PREFERRED EMBODIMENTS

The technical content of the present invention will become apparent by the detailed description of the following embodiments and the illustration of related drawings as follows.

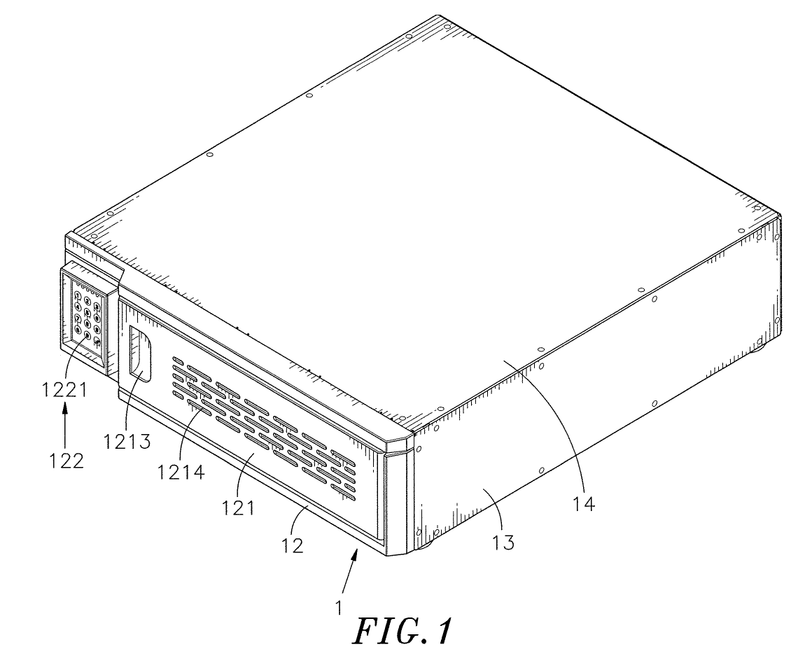

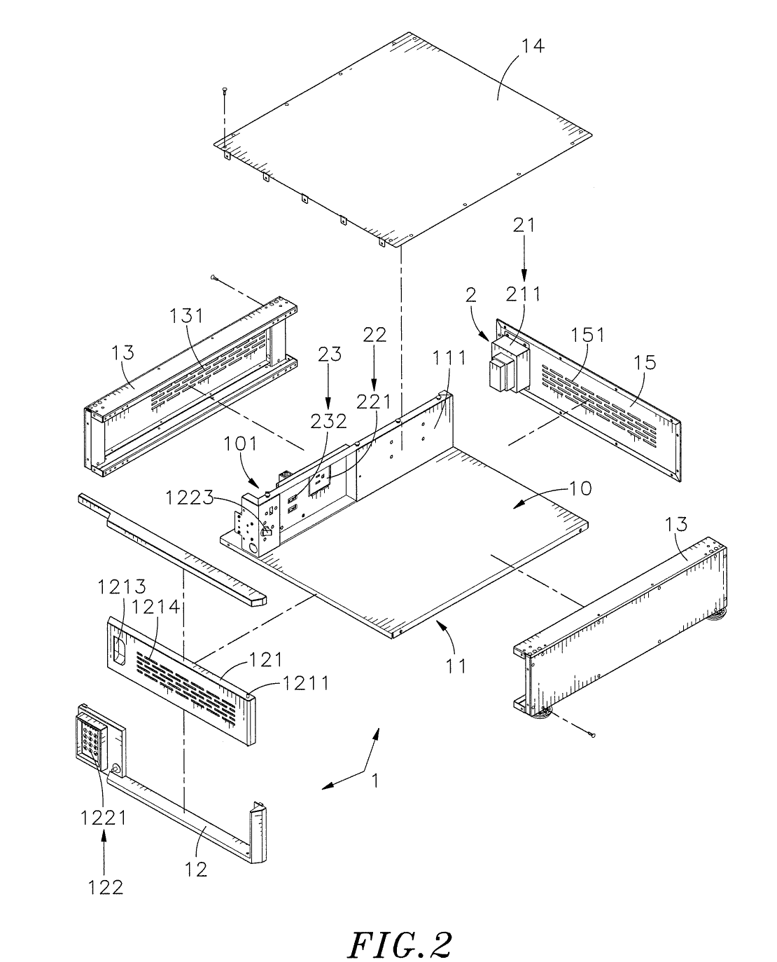

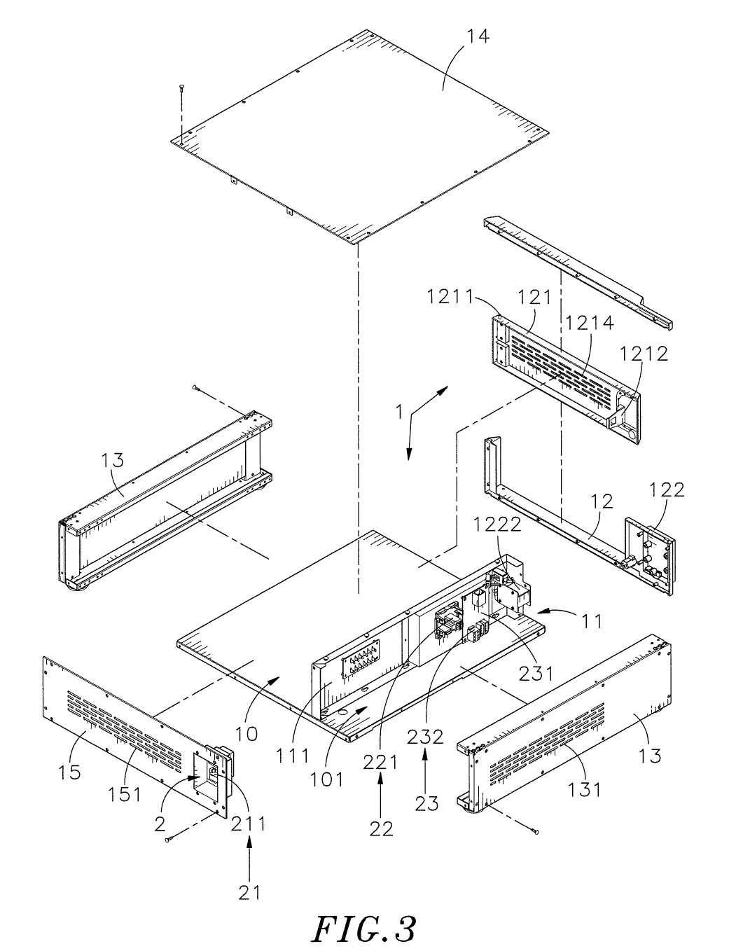

Please refer to FIGS. 1 through 3 which show an elevational view, an exploded view, and other exploded view when viewed from another angle, of a charging cabinet of the present disclosure. As shown in FIGS. 1 through 3, the charging cabinet of the present disclosure includes a main body 1 and a power supply device 2.

The main body 1 has a frame 11 which defines a hollow receiving space 10 therein, and at least one longitudinal support plate 111 is provided in the receiving space 10 to separate the receiving space 10 to form a stowing space 101 smaller than the receiving space 10. A panel 12 is disposed on a front surface of the frame 11, and a hinge lid 121 is movably disposed on the panel 12 corresponding in position to the receiving space 10. A locking device 122 is disposed at a side of the hinge lid 121 and in the front of the stowing space 101, and is configured to control open or lock of the hinge lid 121. Two side plates 13 are uprightly disposed at the frame 11 correspondingly in position to two sides of the panel 12 respectively, and a top plate 14 and a back plate 15 are disposed at and configured to cover the top and back of the frame 11, respectively.

Moreover, the hinge lid 121 of the panel 12 includes a pivot holder 1211 disposed on a side thereof for being pivotally connected to the panel 12, and a clasping sheet 1212 inwardly protruded on the other side thereof, a pulling groove 1213 recessed on an outer surface of the other side thereof, and a plurality of holes 1214 cut therethrough and located between the pulling groove 1213 and the pivot holder 1211. The locking device 122 includes a plurality of buttons 1221 disposed on a side of the hinge lid 121, a lock 1222 disposed on the support plate 111 in the stowing space 101, and a mounting member 1223 protruded on a side of the lock 1222 and inserted through the support plate 111 into the receiving space 10. The locking device 122 can be cooperated with aforesaid members to form a password lock structure. The at least one side plate 13 has a plurality of ventilation holes 131 inserted therethrough, and the back plate 15 has a plurality of heat dissipation holes 151 formed on a surface thereof.

Preferably, the locking device 122 of the panel 12 is a password lock; in actual application, the locking device 122 can be a checkmark lock, a digital lock, a keylock or a fingerprint lock. It should be noted that, upon actual application, the locking device 122 can be implemented and changed by any one of various locks to lock the hinge lid 121 of the panel 12 when the hinge lid 121 is closed. The detailed structure of the locking device 122 is not key feature of present disclosure, so its description is omitted.

The power supply device 2 includes a power input module 21, a power socket module 22 and an expansion connection module 23. The power input module 21 includes at least one adaptor member 211 which can be a power plug or power socket. When the adaptor member 211 is the power socket, a plug formed at an end of a power wire (not shown in figures) can be plugged into the adaptor member 211, and a plug formed at the other end of the power wire can be connected to an external power source, such as commercial power source, a power supplier or a power generator. The plug is plugged into a socket of the external power source to form electrical connection. The adaptor member 211 is electrically connected with the at least one socket 221 of the power socket module 22 via power supply wiring (not shown in figures), so that the adaptor member 211 can provide the socket 221 with AC power inputted from the external power source. The adaptor member 211 is electrically connected to at least one circuit board 231 of the expansion connection module 23 via power supply wiring (not shown in figures). The at least one circuit board 231 includes an adopter circuit, and at least one adaptor socket 232 in the format of USB (Universal Serial Bus) interface disposed on a side surface of the circuit board 231. Therefore, the circuit board 231 can convert AC power inputted from the adaptor member 211 into DC power, and provide DC power to the adaptor socket 232.

To assemble the charging cabinet of the present disclosure, the power input module 21 of the power supply device 2 is disposed on the bottom of the back plate 15 located at back side of the main body 1 first, and the at least one adaptor member 211 is exposed out of the back plate 15. Next, the power socket module 22 and the expansion connection module 23 of the power supply device 2 are disposed in the stowing space 101 of the frame 11, and at least one socket 221 of the power socket module 22 and the circuit board 231 of the expansion connection module 23 are mounted on the support plate 111, so that at least one socket 221 and at least one adaptor socket 232 are disposed on a side of the receiving space 10 for electrical insertion. Next, the panel 12, the two side plate 13, the top plate 14 and the back plate 15 are stably mounted on the frame 11, so that the assembly of the charging cabinet of the present disclosure is completed.

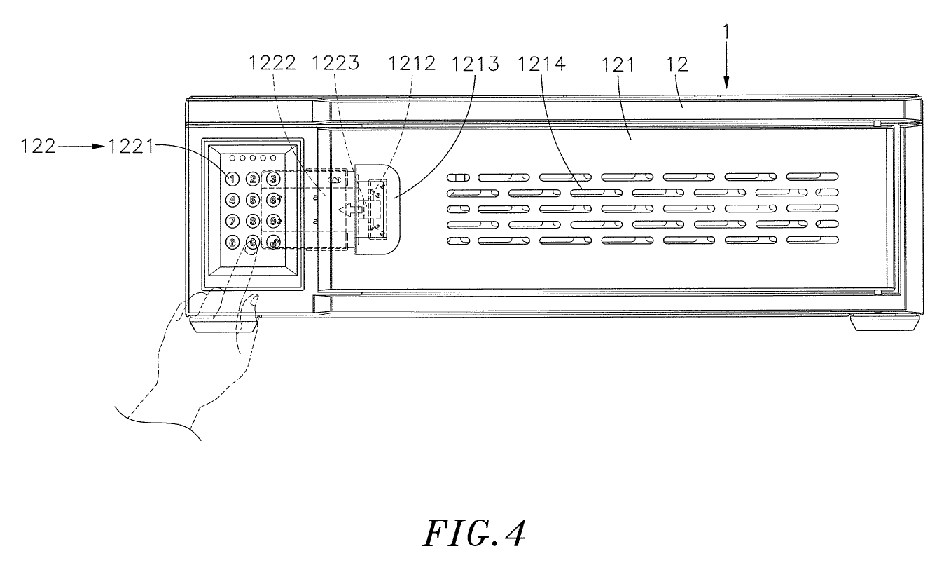

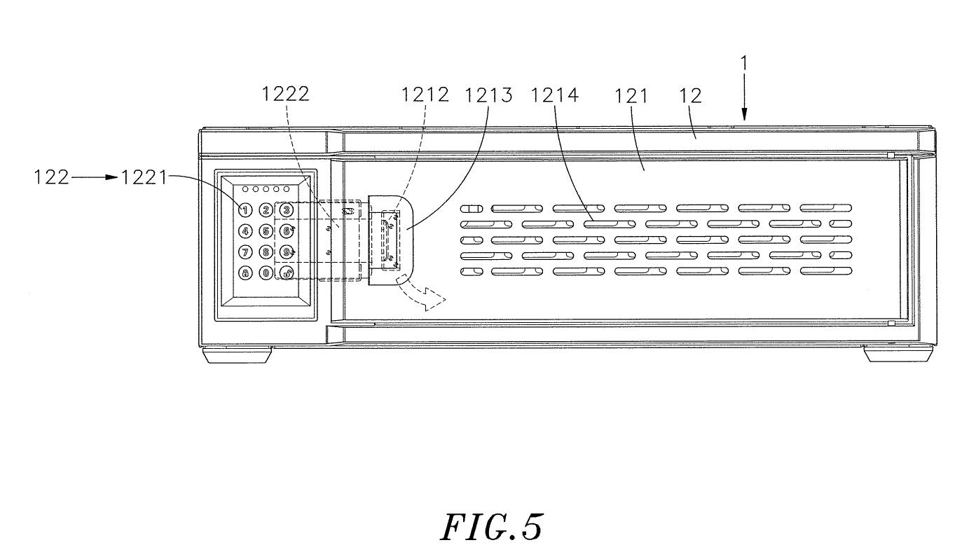

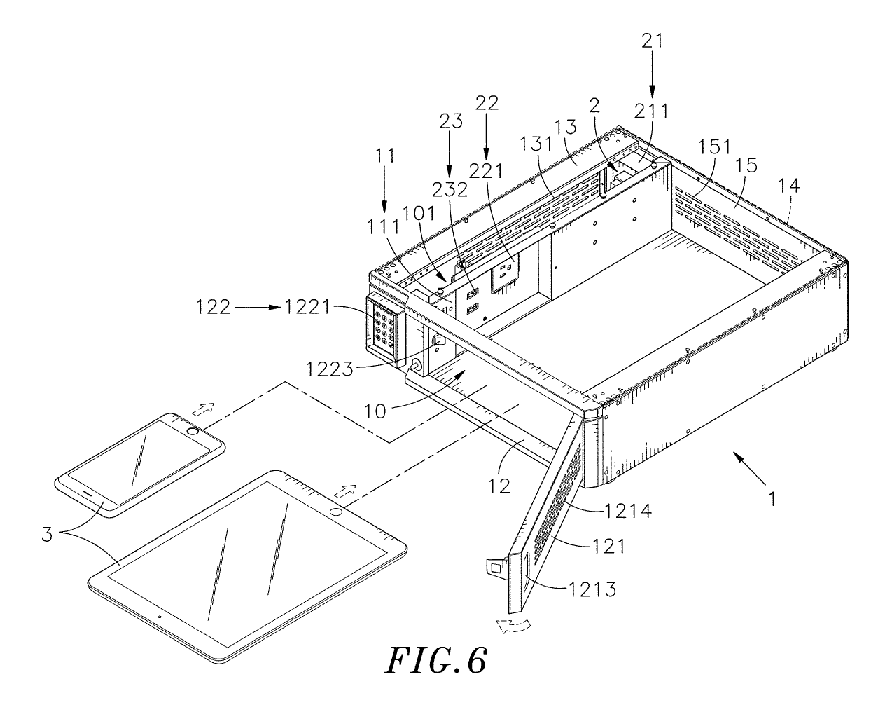

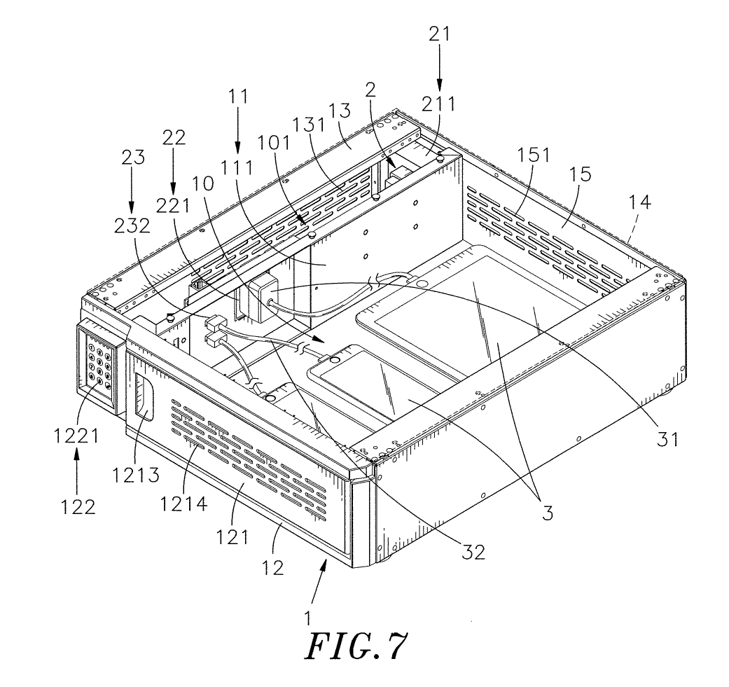

Please refer to FIGS. 4 through 7 which show a partial enlarged view before the locking device is unlocked, a partial enlarged view after the locking device is unlocked, an elevational view before the electronic device is placed into the charging cabinet, and an elevational view when the electronic device is charged in the charging cabinet, in accordance with the present disclosure. The charging cabinet of the present disclosure can be actually applied in department store, hypermarket, stations, swimming pool or school, etc. for temporarily storing article. A user can press the buttons 1221 of the locking device 122 to input a password, and when the inputted password matches with a predetermined password, the lock 1222 is driven to stop the mounting member 1223 from clasping a clasping sheet 1212 disposed at a side of the hinge lid 121. As a result, the user can insert finger to the pulling groove 1213 on the outer surface of the hinge lid 121 and outwardly pull the hinge lid 121. Then, the hinge lid 121 axially rotates about the pivot holder 1211, so as to open the charging cabinet. After opening the charging cabinet, the user can place at least one electronic device 3 (such as smartphone, tablet computer, and notebook computer and so on) in the receiving space 10 of the frame 11, and electrically insert the electronic device 3 to the socket 221 of the power socket module 22 via a charger 31, to form electrical connection; or, the user can electrically insert the electronic device 3 to the adaptor socket 232 of the expansion connection module 23 via a transmission line 32, to form electrical connection. At the same time, the power input module 21 of the power supply device 2 is connected with the external power source, so the electronic device 3 can be charged by the external power source through the power input module 21, the power socket module 22 or the expansion connection module 23. After the user closes the hinge lid 121, the clasping sheet 1212 of the 121 is clasped with the mounting member 1223, so that the locking device 122 locks the hinge lid 121, and the process of using the charge cabinet of the present disclosure to charge the electric device 3 is completed.

At least one electronic device 3 is placed in the receiving space 10 of the frame 11 of the main body 1, so that it is easier for the user to properly arrange the entire space configuration for the electronic device 3 and to centralize management of the electronic device 3. Moreover, at least one electronic device 3 can be electrically inserted in at least one socket 221 or adaptor socket 232 disposed on the support plate 111, that is, the power input module 21 of the power supply device 2 can be connected with the external power source to charge at least one electronic device 3, whereby the user does not need to search other host or power source for charging. As a result, the working hour and cost for charging electronic devices 3 individually can be reduced, and the efficiency of charging operation and convenience in use can be improved.

Furthermore, the main body 1 has the hinge lid 121 disposed at the panel 12 at the front thereof, so the user can open the hinge lid 121 to place the electronic device 3 into the receiving space 10 of the frame 11 for storage or charging operation, or take the electronic device 3 out of the receiving space 10; alternatively, the user can close the hinge lid 121 to lock the hinge lid 121 by the locking device 122, whereby the hinge lid 121 is in a locked state to prevent the electronic device 3 in the receiving space 10 from being lost or stolen.

Therefore, the charging cabinet of the present disclosure has anti-theft function.

The above description is for the purpose of illustration only and shall not be interpreted in any way to limit the scope, configuration or applicability of the present invention. A person skilled in the art may carry out many changes and modifications in the described embodiments without departing from the spirit and the scope of the present invention, which is intended to be limited only by the appended claims.

What is claimed is:

1. A charging cabinet comprising a main body and a power supply device, wherein:
the main body comprises a frame defining a hollow receiving space therein, at least one longitudinal support plate provided in the receiving space to separate the receiving space to form a stowing space smaller than the receiving space, a panel disposed on a front surface of the frame, a hinge lid movably disposed on the panel corresponding in position to the receiving space, a locking device disposed at a side of the hinge lid and in the front of the stowing space and configured to control open or lock of the hinge lid, and two side plates uprightly disposed at the frame with respect to two sides of the panel respectively, and a top plate and a back plate disposed at the top and back of the frame, respectively;
wherein the power supply device comprises a power input module connected with an external power source for supplying power, a power socket module and an expansion connection module electrically connected with the power input module and disposed in the stowing space of the frame, and the power socket module comprises at least one socket disposed on the support plate and configured for electrical insertion of a predetermined electronic device, and the expansion connection module comprises at least one circuit board disposed on the support plate, and the at least one circuit board comprises at least one adaptor socket configured for electrical insertion of the predetermined electronic device, and at least one socket and the at least one adaptor socket are exposed at a side of the receiving space thereof.

2. The charging cabinet according to claim 1, wherein the hinge lid of the panel comprises a pivot holder disposed on a side thereof for being pivotally connected to the panel, and a clasping sheet inwardly protruded on the other side thereof, a pulling groove recessed on an outer surface of the other side thereof, and a plurality of holes cut therethrough and located between the pulling groove and the pivot holder.

3. The charging cabinet according to claim 2, wherein the locking device of the panel comprises a plurality of buttons disposed on a side of the hinge lid, a lock disposed on the support plate and in the stowing space, and a mounting member protruded on a side of the lock and inserted through the support plate into the receiving space for clasping the clasping sheet.

4. The charging cabinet according to claim 1, wherein at least one of the two side plates of the main body has a plurality of ventilation holes inserted therethrough.

5. The charging cabinet according to claim 1, wherein the back plate of the main body has a plurality of heat dissipation holes.

6. The charging cabinet according to claim 1, wherein the power input module of the power supply device comprises an adaptor member connected with the external power source.

7. The charging cabinet according to claim 6, wherein the power input module is disposed on the back plate of the main body, and the adaptor member is exposed out of the back plate, and the adaptor member is a power socket.

8. The charging cabinet according to claim 1, wherein the power input module of the power supply device is configured to output AC power to the power socket module.

9. The charging cabinet according to claim 1, wherein the circuit board of the expansion connection module is configured to convert AC power outputted from the power input module into DC power and output DC power to the adaptor socket.
